(19) United States
(12) Patent Application Publication
(10) Pub. No.: US 2025/0286002 A1
(43) Pub. Date: Sep. 11, 2025

(54) Aluminum Oxide Crystallization Barrier for Hybrid Bonding

(71) Applicant: Applied Materials, Inc., Santa Clara, CA (US)

(72) Inventors: Archana KUMAR, Mountain View, CA (US); Benjamin D. BRIGGS, Merrimack, NH (US); Mariia GORCHICHKO, San Jose, CA (US); Joshua Stuart HOLT, Sunnyvale, CA (US); Shubhendra Kumar JAIN, Belmont, MA (US); William Oghandi CHARLES, Winchester, MA (US); Yoocharn JEON, Palo Alto, CA (US); Roger Allan QUON, Rhinebeck, NY (US); Ryan Thomas LEY, Mountain View, CA (US); Stephen WEEKS, Morrisville, VT (US); Amit PRAKASH, Santa Clara, CA (US)

(21) Appl. No.: 18/599,794

(22) Filed: Mar. 8, 2024

(51) Int. Cl. H01L 23/00

(52) U.S. Cl. CPC H01L 24/08; H01L 24/03; H01L 24/05; H01L 24/80; H01L 2224/0219; H01L 2224/03019; H01L 2224/05647; H01L 2224/08145; H01L 2224/80359; H01L 2224/80895; H01L 2224/80896; H01L 2924/01044; H01L 2924/05432

(57) ABSTRACT

A method for substrate processing for hybrid bonding that includes forming an aluminum oxide crystallization barrier on a metal contact. In some embodiments, the method may include providing a substrate in preparation for a hybrid bonding process where the substrate has an aluminum oxide (Al₂O₃) bonding layer on an uppermost surface of the substrate and a metal contact is present in the aluminum oxide bonding layer. A crystallization barrier is formed on an uppermost surface of the metal contact. The crystallization barrier disrupts crystallization of the aluminum oxide bonding layer caused by interaction of the aluminum oxide material of the aluminum oxide bonding layer and a metal material of the metal contact during a subsequent annealing process of the hybrid bonding process.

### FIELD

Embodiments of the present principles generally relate to semiconductor processing of semiconductor substrates.

### BACKGROUND

Hybrid bonding is the joining or bonding of more than one type of material. In semiconductor manufacturing, hybrid bonding is used to package devices by bonding one substrate or die to another substrate or die to join not only dielectric surfaces but to also join metal interconnects or contacts together. Traditionally, dielectrics, such as silicon dioxide, provide most of the bonding strength in a hybrid bond. As the density of the interconnects and contacts increases, the dielectric material bonding area decreases. To help ensure a successful bond with a die or substrate with a high density of contacts, dielectric materials with higher bonding strengths, such as aluminum oxide, may be introduced into the manufacturing processes. However, the inventors have observed that during hybrid bonding processes that use aluminum oxide, poor bonding occurs between the metal interconnects and contacts, leading to low yields.

Accordingly, the inventors have provided methods for improving hybrid bonding performance of substrates with aluminum oxide bonding layers.

### SUMMARY

Methods for improving hybrid bonding performance by incorporating an aluminum oxide crystallization barrier are provided herein.

In some embodiments, a method for substrate processing may comprise providing a first substrate in preparation for a hybrid bonding process, forming a hybrid bonding layer on the first substrate where the hybrid bonding layer is comprised of an aluminum oxide (Al₂O₃) bonding layer on an uppermost surface of the first substrate, a metal contact, and a crystallization barrier on an uppermost surface of the metal contact where the crystallization barrier disrupts crystallization of the aluminum oxide bonding layer on the metal contact during the hybrid bonding process.

In some embodiments, the method may further include hybrid bonding the first substrate to a second substrate via the hybrid bonding layer, a metal contact that is copper, a crystallization barrier that is formed of a material with a crystal lattice structure different from a crystal lattice structure of the metal contact, a material that is ruthenium with a hexagonal close-packed (HCP) crystal lattice structure with a lattice constant of 2.7 angstroms, a crystallization barrier that is formed of a material with a crystal lattice structure similar to a crystal lattice structure of the metal contact, a material that is cobalt with a face-centered cubic (FCC) crystal lattice structure which has a lattice constant of 3.9 angstroms, a crystallization barrier that has a thickness of one monolayer, a crystallization barrier has a thickness of greater than zero to approximately 2 nm, a crystallization barrier that is formed using a selective atomic layer deposition (ALD) process, an uppermost surface of the metal contact that has a recess below an uppermost surface of the aluminum oxide bonding layer and where the crystallization barrier has a thickness less than the recess such that the metal contact can expand during a subsequent annealing process of the hybrid bonding process, an aluminum oxide bonding layer that is formed on silicon dioxide, and/or an aluminum oxide bonding layer that is formed on silicon carbon nitride.

In some embodiments, a substrate prepared for hybrid bonding that comprises a dielectric material, a dielectric bonding layer formed on the dielectric material, at least one metal contact, and a crystallization barrier on the uppermost surface of the metal contact where an uppermost surface of the crystallization barrier is exposed in the dielectric bonding layer and where the crystallization barrier has a crystal lattice structure that disrupts crystallization of the dielectric bonding layer.

In some embodiments, the substrate may further include a dielectric bonding layer that is an aluminum oxide (Al₂O₃) layer and where at least one of the at least one metal contact is copper, a crystallization barrier that is formed of a material with a crystal lattice structure different from a crystal lattice structure of the metal contact, a crystallization barrier that is formed of a material with a crystal lattice structure similar to a crystal lattice structure of the metal contact, a crystallization barrier that has a thickness of one monolayer, and/or the substrate and another substrate that is hybrid bonded to the substrate via the dielectric bonding layer and the at least one metal contact.

In some embodiments, a non-transitory, computer readable medium having instructions stored thereon that, when executed, cause a method for substrate processing to be performed, the method may comprise providing a substrate in preparation for a hybrid bonding process, forming a hybrid bonding layer on the substrate where the hybrid bonding layer is comprised of an aluminum oxide (Al₂O₃) bonding layer on an uppermost surface of the substrate, a metal contact, and a crystallization barrier on an uppermost surface of the metal contact where the crystallization barrier disrupts crystallization of the aluminum oxide bonding layer on the metal contact during the hybrid bonding process.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 is a method for preparing a substrate for hybrid bonding in accordance with some embodiments of the present principles.

FIG. 2 depicts a cross-sectional view of a substrate in preparation for a hybrid bonding process in accordance with some embodiments of the present principles.

FIG. 3 depicts a cross-sectional view of a substrate with an aluminum oxide crystallization barrier formed on a metal contact of the substrate in accordance with some embodiments of the present principles.

FIG. 4 depicts cross-sectional views of a hybrid bonding process without an aluminum oxide crystallization barrier of the present principles.

FIG. 5 depicts cross-sectional views of a hybrid bonding process using metal contacts with aluminum oxide crystallization barriers in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods provide improved hybrid bonding performance by providing an aluminum oxide crystallization barrier on the uppermost surface of the metal contacts. The aluminum oxide crystallization barrier prevents the bonding surfaces of the metal contacts from interacting with the aluminum oxide during annealing processes associated with a hybrid bonding process, enabling both high dielectric and contact bonding strengths. The high bonding strengths provided by the present methods enable increased metal contact densities to be achieved, allowing for scaling of semiconductor devices. The present techniques may be performed using a selective deposition process to deposit the aluminum oxide crystallization barrier only on metal contacts of a substrate, providing a fast and efficient process for preventing metal contact bonding failures in hybrid bonding processes using aluminum oxide bonding layers.

Traditional dielectrics such as silicon dioxide limit the scaling of devices due to the bonding strength of the dielectric material. To increase the metal contact densities, the bonding strength of the dielectrics used in hybrid bonding must be increased as the bonding strength of the metal contacts is relatively low compared to the dielectric bonding strength. Aluminum oxide is being considered as a replacement for dielectric materials such as silicon dioxide or silicon carbon nitride. Aluminum oxide has a 40% to 80% increase in bonding strength compared to that of silicon dioxide or silicon carbon nitride. However, the inventors have found that when a substrate with an aluminum oxide bonding layer and metal contacts are bonded together and then annealed, the aluminum oxide migrates over the top surfaces of the metal contacts and prevents the metal contacts from bonding. The inventors believe that the migration of the aluminum oxide is caused by low-temperature crystallization of the aluminum oxide. Typically, aluminum oxide crystallizes at a temperature of approximately 850 degrees Celsius. Hybrid bonding annealing temperatures are generally around 350 degrees Celsius. The inventors believe that the crystals of the metal material (e.g., copper, etc.) of the metal contacts acts as a catalyst for the crystallization of the aluminum oxide which lowers the crystallization temperature to at or below the annealing temperature. The low temperature causes the aluminum oxide to crystallize and migrate/diffuse over the surfaces of the metal contacts during annealing of the bonded substrate (e.g., the aluminum oxide has a higher diffusion rate than copper at a given temperature causing aluminum oxide to migrate).

The inventors found that to successfully bond using an aluminum oxide bonding layer, the aluminum oxide crystallization caused by contacting the upper surface or bonding surface of the copper contact and the subsequent migration should be minimized. In the present methods, suppression of the aluminum oxide migration during hybrid bonding may be accomplished by providing an aluminum oxide crystallization barrier that protects the bonding surface of the metal contacts from interacting with the aluminum oxide bonding layer during the annealing processes. The material of the aluminum oxide crystallization barrier may be materials that disrupt the crystallization of the aluminum oxide either by having a crystal lattice structure dissimilar to that of the metal material of the metal contacts or by having a crystal lattice structure similar to that of the metal material of the metal contacts. The inventors found that disruption of the aluminum oxide crystallization can be accomplished with aluminum oxide crystallization barriers as thin as one monolayer. In some embodiments, the upper thickness limit is less than a dishing recess depth to allow expansion of the metal contact material during annealing.

The aluminum oxide crystallization barrier represses the grain nucleation (location at which crystal growth begins) by using elements that disrupt the aluminum oxide crystal lattice to prevent the crystallization at low temperatures (approximately 300 degrees Celsius to approximately 400 degrees Celsius). For example, but not meant to be limiting, the aluminum oxide crystallization barrier may be formed of specific lattice structure variants of cobalt (similar) or ruthenium (dissimilar) when copper is used as the metal contact material. Copper has a face-centered cubic (FCC) lattice structure with a lattice constant of 3.61 A. Lattice structure variants of cobalt may have an FCC lattice structure with a lattice constant of 3.49 A. The cobalt lattice structure variant is close enough in lattice constant value to copper to allow easy growth of the cobalt variant onto copper, but different enough from the lattice structure of copper to prevent the aluminum oxide from crystallizing and migrating over the top surface of the metal contact when the aluminum oxide comes into contact with the cobalt (instead of in contact with the copper).

Ruthenium lattice variants may have a hexagonal close-packed (HCP) lattice structure with a lattice constant of 2.76 A. The ruthenium lattice structure is dramatically different from that of copper such that the aluminum oxide does not crystallize and migrate over the top surface of the metal contact when the aluminum oxide comes into contact with the ruthenium (instead of in contact with the copper). The conductivity of the aluminum oxide crystallization barrier material must also be considered, as the aluminum oxide crystallization barrier becomes part of the bonded metal contact. If resistance is not negligible, the aluminum oxide crystallization barrier material will impact the performance of the metal contact. The thickness of the aluminum oxide crystallization barrier material can also impact the performance of the metal contact if the resistance of the material is greater than the underlying metal contact material (contact resistance increases as the thickness increases).

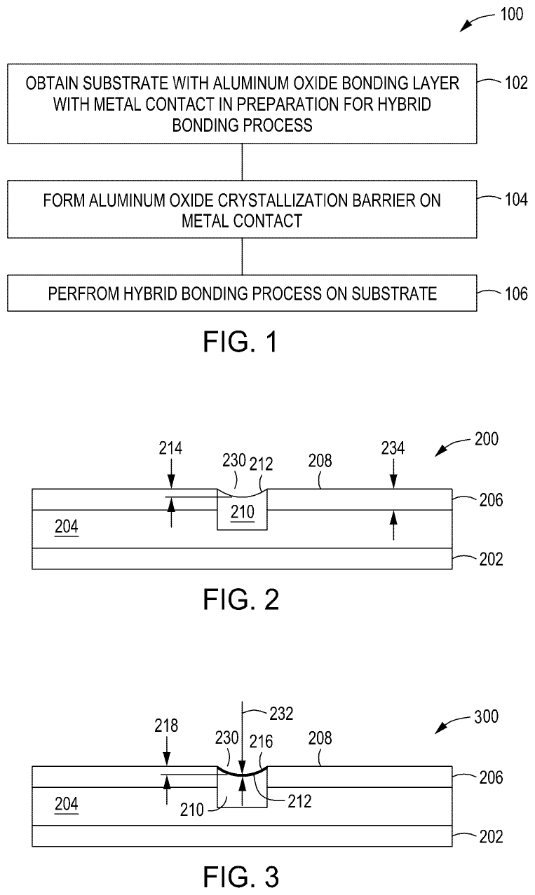

FIG. 1 is a method 100 for preparing a substrate 202 for hybrid bonding. In block 102, a substrate is obtained in preparation for the hybrid bonding process as depicted in a view 200 of FIG. 2. The substrate 202 may be formed, at least in part, of a dielectric layer 204 such as, but not limited to, silicon dioxide or silicon carbon nitride dielectric materials and the like. In some embodiments, the substrate 202 may have undergone prior device manufacturing and/or packaging processes to prepare the substrate 202 for bonding to another substrate and/or die. The substrate 202 has an aluminum oxide bonding layer 206 with a metal contact 210. The aluminum oxide bonding layer 206 may have a thickness 234 of approximately 30 nm to approximately 50 nm. In some embodiments, the substrate 202 may undergo a chemical mechanical planarization (CMP) process to remove portions of the aluminum oxide bonding layer 206 and/or to dish or make a recess 230 on an uppermost surface 212 of the metal contact 210 below an uppermost surface 208 of the aluminum oxide bonding layer 206. In some embodiments, the recess 230 may have a depth 214 of approximately 5 nm to approximately 10 nm. The recess 230 allows for the metal material of the metal contact 210 to expand during the annealing process of the hybrid bonding process and bond together with a metal contact on another substrate or die.

In block 104, an aluminum oxide crystallization barrier 216 is formed on the uppermost surface 212 of the metal contact 210 as depicted in a view 300 of FIG. 3. The deposition of the aluminum oxide crystallization barrier 216 may be accomplished using any type of selective deposition process compatible with back end of line (BEOL) substrates and thermal budgets (typically, e.g., 400 degrees or less). The thickness 232 of the aluminum oxide crystallization barrier 216 may be from one monolayer to approximately 2 nm. In some embodiments, the thickness 232 is one monolayer and is deposited using atomic layer deposition (ALD) processes. The thickness 232 of the aluminum oxide crystallization barrier 216 has a negligible impact on the amount of expansion, and subsequent volume change, of the metal material of the metal contact 210 during annealing processes. The aluminum oxide crystallization barrier 216 does not impact the temperatures of the annealing processes of the hybrid bonding process. The depth 218 of the recess 230 after formation of the aluminum oxide crystallization barrier 216 is less than the depth 214 of the recess 230 before deposition of the aluminum oxide crystallization barrier 216. The depth 218 is still sufficient to allow expansion of the metal contact 210 during the annealing process of the hybrid bonding process. In some embodiments, the depth 218 may be from approximately 3 nm to approximately 5 nm or more depending on the thickness 232 of the aluminum oxide crystallization barrier 216. The aluminum oxide bonding layer 206, the metal contact 210, and the aluminum oxide crystallization barrier 216 form a hybrid bonding layer on the substrate 202.

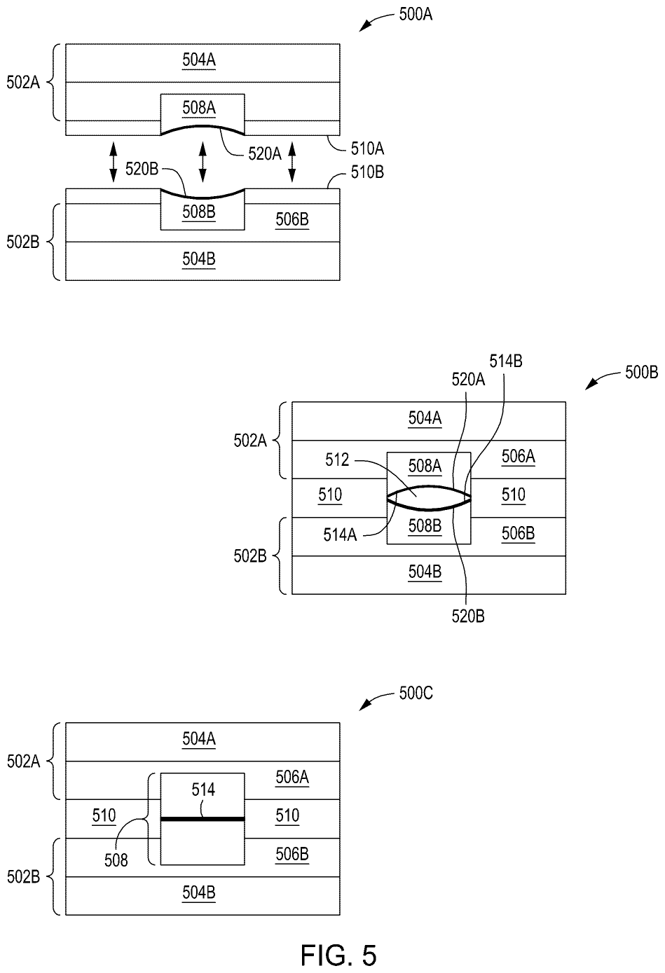

In block 106, a hybrid bonding process is performed on the substrate 202 to bond the substrate 202 to another substrate or die (see FIG. 5 and description below). The hybrid bonding process includes first bonding the dielectric materials together by bringing the aluminum oxide bonding layer 206 into contact with another aluminum oxide bonding layer. When the dielectric materials make contact, the dielectric materials bond together. In some embodiments, the hybrid bonding process may also include adding additional force to press the dielectric materials together. After the dielectric materials are bonded, the metal contact 210 remains unbonded. The bonding of the metal contacts requires heat to expand the metals of the metal contact such that the metal contacts bond to each other. The annealing process of the hybrid bonding process is performed at a temperature of approximately 300 degrees Celsius to approximately 400 degrees Celsius. As the metal material of the metal contact expands, the aluminum oxide crystallization barrier 216 makes contact with another aluminum oxide crystallization barrier of another metal contact on another substrate, bonding the metal contacts together. The aluminum oxide crystallization barrier 216 prevents the aluminum oxide material of the aluminum oxide bonding layer 206 from coming into contact with the underlying metal material of the metal contact 210, preventing aluminum oxide crystallization and migration over the uppermost surface 212 of the metal contact 210.

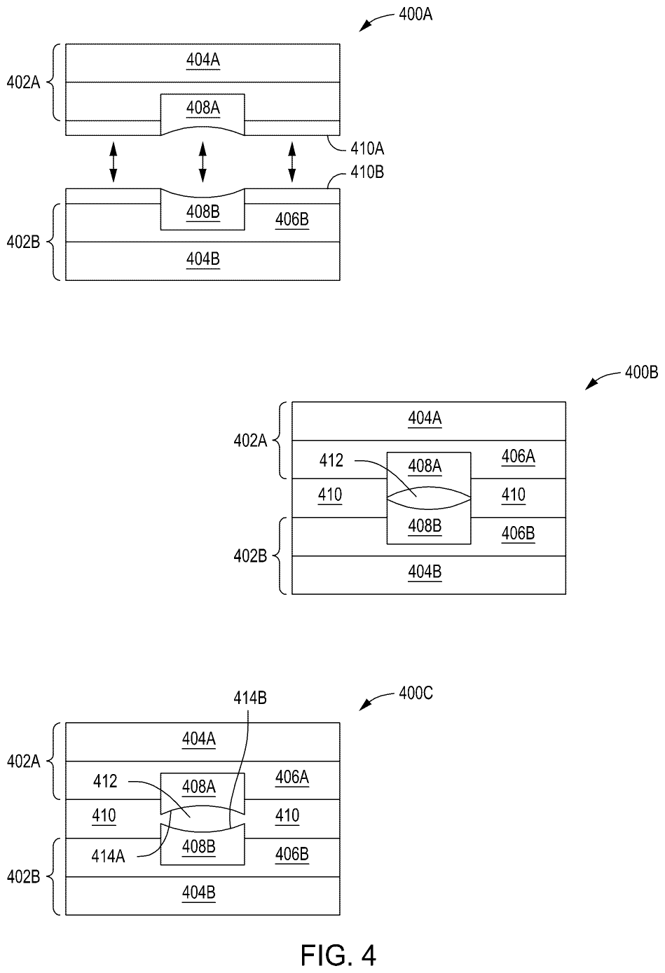

The above methods can be used to enhance the bonding strength and yield of hybrid bonding processes. For example, as depicted in a view 400A of FIG. 4, the substrates 402A, 402B may be bonded together. The substrates 402A, 402B have silicon layers 404A, 404B, silicon dioxide layers 406A, 406B (or silicon carbon nitride layers and the like), and metal contacts 408A, 408B. The bonding layers are aluminum oxide bonding layers 410A, 410B. As depicted in a view 400B of FIG. 4, when the substrates 402A, 402B with the aluminum oxide bonding layers 410A, 410B are brought into contact with each other (bonded), the aluminum oxide bonding layers 410A, 410B form a single aluminum oxide bonded layer 410. The metal contacts 408A, 408B have not yet bonded together, and a gap 412 exists between the metal contacts 408A, 408B due to the recesses formed on each metal contact during CMP processing. To close the gap 412 and form a continuous contact, the substrates 402A, 402B undergo an annealing process at temperatures up to approximately 400 degrees Celsius. The inventors have found that during the annealing process, the aluminum oxide material of the aluminum oxide bonding layers crystallize at a dramatically lower temperature (at approximately 400 degrees Celsius or less compared to a normal crystallization temperature of approximately 850 degrees Celsius) due to the material (e.g., copper, etc.) of the metal contacts acting as a crystallization catalyst. As depicted in a view 400C of FIG. 4, the substantially lowered crystallization temperature allows the single aluminum oxide bonded layer 410 to crystallize and migrate over the surfaces 414A, 414B of the metal contacts 408A, 408B during the annealing process, preventing the metal contacts 408A, 408B from bonding together.

As depicted in a view 500A of FIG. 5, the substrates 502A, 502B may be bonded together using the present methods as described above. In some embodiments, the substrates 502A, 502B may include dielectric layers such as, but not limited to, silicon dioxide and/or silicon carbon nitride and the like. In the example, the substrates 502A, 502B have silicon layers 504A, 504B, silicon dioxide layers 506A, 506B (or silicon carbon nitride layers and the like), and metal contacts 508A, 508B. The bonding layers are aluminum oxide bonding layers 510A, 510B. The metal contacts 508A, 508B have aluminum oxide crystallization barriers 520A, 520B on the uppermost or bonding surfaces of the metal contacts 508A, 508B. As depicted in a view 500B of FIG. 5, when the substrates 502A, 502B are brought into contact with each other (bonded), the aluminum oxide bonding layers 510A, 510B form a single aluminum oxide bonded layer 510. The metal contacts 508A, 508B have not yet bonded together, and a gap 512 exists between the metal contacts 508A, 508B due to the recesses formed on each metal contact during CMP processing.

To close the gap 512 and form a continuous contact, the substrates 502A, 502B undergo an annealing process at temperatures up to approximately 400 degrees Celsius. The inventors discovered that by forming the aluminum oxide crystallization barriers 520A, 520B on the metal contacts 508A, 508B prior to the annealing process, the aluminum oxide material did not crystallize at the lower annealing temperatures (at approximately 300 degrees Celsius to approximately 400 degrees Celsius). As depicted in a view 500C of FIG. 5, the single aluminum oxide bonded layer 510 does not crystallize and migrate over the surfaces 514A, 514B of the metal contacts 508A, 508B during the annealing process, allowing the metal contacts 508A, 508B to expand, and the aluminum oxide crystallization barriers 520A, 520B to bond together to form a single aluminum oxide crystallization barrier 514 and a bonded contact 508.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. A method for substrate processing, comprising:
providing a first substrate in preparation for a hybrid bonding process;
forming a hybrid bonding layer on the first substrate, the hybrid bonding layer comprised of:
an aluminum oxide (Al₂O₃) bonding layer on an uppermost surface of the first substrate;
a metal contact; and
a crystallization barrier on an uppermost surface of the metal contact, wherein the crystallization barrier disrupts crystallization of the aluminum oxide bonding layer on the metal contact during the hybrid bonding process.

2. The method of claim 1, further comprising:
hybrid bonding the first substrate to a second substrate via the hybrid bonding layer.

3. The method of claim 1, wherein the metal contact is copper.

4. The method of claim 1, wherein the crystallization barrier is formed of a material with a crystal lattice structure different from a crystal lattice structure of the metal contact.

5. The method of claim 4, wherein the material is ruthenium with a hexagonal close-packed (HCP) crystal lattice structure with a lattice constant of 2.7 angstroms.

6. The method of claim 1, wherein the crystallization barrier is formed of a material with a crystal lattice structure similar to a crystal lattice structure of the metal contact.

7. The method of claim 6, wherein the material is cobalt with a face-centered cubic (FCC) crystal lattice structure which has a lattice constant of 3.9 angstroms.

8. The method of claim 1, wherein the crystallization barrier has a thickness of one monolayer.

9. The method of claim 1, wherein the crystallization barrier has a thickness of greater than zero to approximately 2 nm.

10. The method of claim 1, wherein the crystallization barrier is formed using a selective atomic layer deposition (ALD) process.

11. The method of claim 1, wherein the uppermost surface of the metal contact has a recess below an uppermost surface of the aluminum oxide bonding layer and wherein the crystallization barrier has a thickness less than the recess such that the metal contact can expand during a subsequent annealing process of the hybrid bonding process.

12. The method of claim 1, wherein the aluminum oxide bonding layer is formed on silicon dioxide.

13. The method of claim 1, wherein the aluminum oxide bonding layer is formed on silicon carbon nitride.

14. A substrate prepared for hybrid bonding, comprising:
a dielectric material;
a dielectric bonding layer formed on the dielectric material;
at least one metal contact; and
a crystallization barrier on an uppermost surface of the metal contact, wherein an uppermost surface of the crystallization barrier is exposed in the dielectric bonding layer and wherein the crystallization barrier has a crystal lattice structure that disrupts crystallization of the dielectric bonding layer.

15. The substrate of claim 14, wherein the dielectric bonding layer is an aluminum oxide (Al₂O₃) layer and wherein at least one of the at least one metal contact is copper.

16. The substrate of claim 14, wherein the crystallization barrier is formed of a material with a crystal lattice structure different from a crystal lattice structure of the metal contact.

17. The substrate of claim 14, wherein the crystallization barrier is formed of a material with a crystal lattice structure similar to a crystal lattice structure of the metal contact.

18. The substrate of claim 14, wherein the crystallization barrier has a thickness of one monolayer.

19. A device, comprising:
the substrate of claim 14; and
another substrate that is hybrid bonded to the substrate via the dielectric bonding layer and the at least one metal contact.

20. A non-transitory, computer readable medium having instructions stored thereon that, when executed, cause a method for substrate processing to be performed, the method comprising:
providing a substrate in preparation for a hybrid bonding process;
forming a hybrid bonding layer on the substrate, the hybrid bonding layer comprised of:
an aluminum oxide (Al₂O₃) bonding layer on an uppermost surface of the substrate;
a metal contact; and
a crystallization barrier on an uppermost surface of the metal contact, wherein the crystallization barrier disrupts crystallization of the aluminum oxide bonding layer on the metal contact during the hybrid bonding process.
